(19) United States
(12) Patent Application Publication
(10) Pub. No.: US 2024/0319265 A1
(43) Pub. Date: Sep. 26, 2024

(54) SEMICONDUCTOR TEST DEVICES, SYSTEMS INCLUDING THE SAME, AND METHODS FOR TESTING THE SAME

(71) Applicant: SAMSUNG ELECTRONICS CO., LTD., Suwon-si (KR)

(72) Inventors: Seongkwan LEE, Suwon-si (KR); Junyeon WON, Suwon-si (KR); Minho KANG, Suwon-si (KR); Cheolmin PARK, Suwon-si (KR); Jaemoo CHOI, Suwon-si (KR)

(21) Appl. No.: 18/609,802

(22) Filed: Mar. 19, 2024

(30) Foreign Application Priority Data
Mar. 20, 2023 (KR) 10-2023-0036166
May 17, 2023 (KR) 10-2023-0063809

(51) Int. Cl. G01R 31/28

(52) U.S. Cl. CPC G01R 31/2896; G01R 31/287

(57) ABSTRACT

A test device for testing a semiconductor, the test device comprising: a pulse signal generator that is configured to generate a first pulse signal and transmit the first pulse signal through channels; a sampler that is configured to receive the first pulse signal through the channels and conduct a sampling process on the first pulse signal, based on a second pulse signal; a width analyzer that is configured to measure a first width of the first pulse signal and generate a first measurement value, based on a result of the sampling process; and a calculator that is configured to output a test result corresponding to each of the channels of the test device, based on the first measurement value.

### CROSS-REFERENCE TO RELATED APPLICATION

This application is based on and claims priority under 35 U.S.C. § 119 to Korean Patent Application No. 10-2023-0036166, filed on Mar. 20, 2023, and Korean Patent Application No. 10-2023-0063809, filed on May 17, 2023, in the Korean Intellectual Property Office, the disclosures of which are incorporated by reference herein in their entireties.

### BACKGROUND

The inventive concept of the present disclosure relates to electronic devices, and more particularly, to semiconductor test devices, systems including the same, and methods of testing the same.

Semiconductor test devices may test semiconductor devices by transmitting or receiving a signal to or from the semiconductor devices. The importance of test processes for semiconductor devices is increasing to improve the quality and productivity of the semiconductor devices.

However, with increases (e.g., increased requirements or enhanced parameters) in the specifications of electronic products, highly integrated semiconductor devices, including various functions, are being developed, and the time and costs consumed during test processes for quality assurance of the highly integrated semiconductor devices may increase.

### SUMMARY

The inventive concept of the present disclosure provides a device, system, and method in which a defect in a semiconductor test device is more precisely determined, and the time and costs consumed for the determination are further reduced than conventional technologies.

According to an aspect of the inventive concept, there is provided a test device for testing a semiconductor, the test device comprising: a pulse signal generator that is configured to generate a first pulse signal and transmit the first pulse signal through channels; a sampler that is configured to receive the first pulse signal through the channels and conduct a sampling process on the first pulse signal, based on a second pulse signal; a width analyzer that is configured to measure a first width of the first pulse signal and generate a first measurement value, based on a result of the sampling process; and a calculator that is configured to output a test result corresponding to each of the channels of the test device, based on the first measurement value.

According to another aspect of the inventive concept, there is provided a test device for testing a semiconductor, the test device comprising: a pulse signal generator that is configured to generate a test signal; a plurality of channels that is configured to transmit the test signal; a sampler that is configured to receive the test signal through at least one channel of the plurality of channels and conduct a sampling process on the test signal based on a pulse signal; a width analyzer that is configured to generate a first measurement value by measuring a first width of the test signal based on a result of the sampling process; and a calculator that is configured to output a test result corresponding to each of the at least one channel of the test device, based on the first measurement value.

According to another aspect of the inventive concept, there is provided a test device that is configured to test a semiconductor device, wherein the test device is further configured to: generate a test signal and transmit the test signal through channels; convert the test signal into digital data by sampling the test signal; measure values of widths of the test signal, based on the digital data; generate a detection signal by detecting a corresponding value of a width of the test signal among the values of the widths of the test signal; count in response to the detection signal to generate a counting result; and calculate a weighted average value of the values of the widths of the test signal, based on the counting result and the values of the widths of the test signal.

### BRIEF DESCRIPTION OF THE DRAWINGS

Embodiments will be more clearly understood from the following detailed description taken in conjunction with the accompanying drawings in which:

FIG. 1 is a block diagram schematically showing a semiconductor test system according to some embodiments;

FIG. 2 is a waveform diagram for describing a phenomenon in which a pulse signal is distorted during a signal transmitting process;

FIG. 3 is a block diagram showing a portion of a semiconductor test device, according to some embodiments;

FIG. 4 is a block diagram showing a sampler and a pulse signal generator of a semiconductor test device, according to some embodiments;

FIG. 5 is a waveform diagram showing a process of sampling a pulse signal, according to some embodiments;

FIG. 6 is a block diagram showing an analyzer configured to measure a width of a pulse signal, according to some embodiments;

FIG. 7 is a waveform diagram showing a width measuring process according to various types of sampling of a pulse signal, according to some embodiments;

FIG. 8 is a graph for describing a weighted average calculation for a width of a pulse signal, according to some embodiments;

FIG. 9 is a block diagram showing a calculator of a semiconductor test device, according to some embodiments;

FIG. 10 is a flowchart of a method of testing a semiconductor test device, according to some embodiments;

FIG. 11 is a flowchart of a width measuring method and/or an average value calculating method for a test signal, according to some embodiments;

FIG. 12 is a flowchart of a process for measuring a width of a test signal, according to some embodiments; and

FIG. 13 is a flowchart of a weighted average calculating process for a width of a test signal, according to some embodiments.

### DETAILED DESCRIPTION OF THE EMBODIMENTS

Hereinafter, embodiments will be described in detail with reference to accompanying drawings.

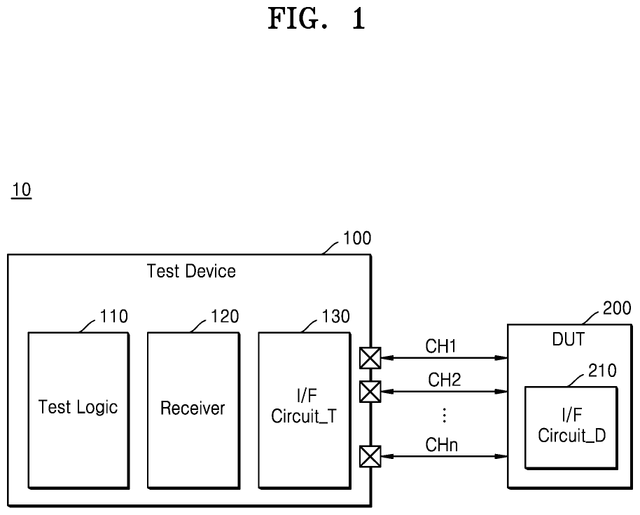

FIG. 1 is a block diagram schematically showing a semiconductor test system 10 according to some embodiments.

Referring to FIG. 1, the semiconductor test system 10 may include a semiconductor test device 100, a device under test (DUT) 200, and channels CH1 to CHn electrically connecting the semiconductor test device 100 and the DUT 200 to each other. Various elements may be mounted on a test board to perform a test operation on the DUT 200, and the test board may be embodied in various forms. For example, the DUT 200 may communicate with the semiconductor test device 100 through the test board. In some embodiments, the semiconductor test device 100 may communicate with the DUT 200 mounted on the test board. The semiconductor test device 100 may be variously realized without being limited to FIG. 1. For example, the channels CH1 to CHn may be configurations included in the semiconductor test device 100.

A test process (also referred to as a test or a test operation) for determining a defect of a semiconductor device (e.g., the DUT 200) may be performed in various stages of a semiconductor process (e.g., in various manufacturing processes of the semiconductor device), and for example, may include a wafer level test and a wafer level post-test. The wafer level test may correspond to a test for individual semiconductor dies in a wafer level. The wafer level post-test may be a test for a semiconductor die before packaging is performed or a test for a semiconductor package obtained by packaging one semiconductor die (or one semiconductor chip). In some embodiments, the test for the semiconductor package may be a test for a semiconductor package including a plurality of semiconductor chips. In other words, a test for the DUT 200, which is described in the present specification, may be variously realized.

According to some embodiments, the semiconductor test device 100 may include a semiconductor chip, such as a field programmable gate array (FPGA), an application specific integrated circuit (ASIC), or an application processor (AP), and may perform the test operation on the DUT 200 as the DUT 200 is mounted on the test board, as shown in FIG. 1. Also, while testing the DUT 200, the semiconductor test device 100 may provide signals (e.g., test signals for the DUT 200) to the DUT 200 through the channels CH1 to CHn in parallel. Similarly, the semiconductor test device 100 may receive signals (e.g., test results of the DUT 200) from the DUT 200 through the channels CH1 to CHn in parallel.

According to some embodiments, each of the channels CH1 to CHn may denote at least one of transmission paths (e.g., conductive lines or wiring circuits) through which a signal is transmitted or received to or from the semiconductor test device 100. In some embodiments, each of the channels CH1 to CHn may be referred to as a path included in a printed circuit board, a connector, and/or a cable in the semiconductor test device 100. When minor damage (e.g., a defect) is present in the channels CH1 to CHn, a distortion phenomenon may occur in signals transmitted or received through the channels CH1 to CHn.

The semiconductor test device 100 may include a test logic 110, a receiver 120, and a test interface circuit (I/F Circuit_T) 130. The semiconductor test device 100 may further include various elements, such as a communication device configured to communicate with an external device or a host that requests a test, a memory temporarily storing various types of information related to various tests, and a power supply circuit configured to provide power to the DUT 200. As such, the semiconductor test system 10 according to an embodiment may be variously defined by elements for testing the DUT 200. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

According to some embodiments, the test logic 110 may, in general, control test operations for the DUT 200 based on the test signal for the DUT 200, and accordingly, the semiconductor test device 100 may determine whether the DUT 200 normally operates. The receiver 120 may be referred to as a configuration for receiving a signal transmitted to the semiconductor test device 100 (or a signal transmitted or received within the semiconductor test device 100). For example, the receiver 120 may include a semiconductor chip, such as an FPGA configured to receive a signal transmitted through the channels CH1 to CHn.

According to some embodiments, during a process in which a signal is transmitted or received through the channels CH1 to CHn, the signal may be modified (e.g., distorted) when a channel among the channels CH1 to CHn is abnormal (e.g., damaged) as described above. As will be described in detail below, the semiconductor test device 100 according to some embodiments may detect abnormality in a channel among the channels CH1 to CHn by transmitting or receiving a signal (e.g., a test signal for the semiconductor test device 100) through the channels CH1 to CHn.

According to some embodiments, the DUT 200 may be any type of semiconductor device and for example, may be a memory device including a semiconductor memory cell array. For example, the memory device may include dynamic random access memory (DRAM), such as double data rate (DDR) synchronous dynamic random access memory (SDRAM), low power double data rate (LPDDR) SDRAM, graphics double data rate (GDDR) SDRAM, or Rambus dynamic random access memory (RDRAM). In some embodiments, the memory device may correspond to a nonvolatile memory, such as flash memory, magnetic random access memory (MRAM), ferroelectric random access memory (FeRAM), phase change random access memory (PRAM), or resistive random access memory (ReRAM).

The DUT 200 may include a DUT interface circuit (I/F Circuit_D) 210 configured to communicate with the semiconductor test device 100. The DUT 200 may be configured to receive the test signals for the DUT 200 from the semiconductor test device 100 through the channels CH1 to CHn, and store data according to the received test signals for the DUT 200 in a memory cell array (not shown). Also, the DUT 200 may be configured to read data stored in the memory cell array and provide test results of the DUT 200 according to the read data to the semiconductor test device 100 through the I/F Circuit_D 210 and the channels CH1 to CHn.

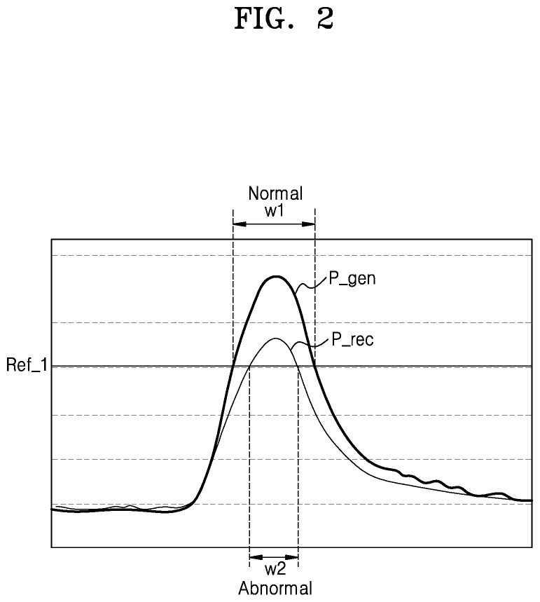

FIG. 2 is a waveform diagram for describing a phenomenon in which a pulse signal is distorted during a signal transmitting process.

Referring to FIGS. 1 and 2, a signal may be modified (e.g., distorted) during a signal transmitting process through the channels CH1 to CHn. According to some embodiments, the semiconductor test device 100 may determine whether the channels CH1 to CHn are abnormal by transmitting or receiving a signal through the channels CH1 to CHn. For example, the semiconductor test device 100 may generate a pulse signal P_gen. The pulse signal P_gen may be transmitted through the channels CH1 to CHn. A signal generated based on the pulse signal P_gen may be received by the receiver 120 again through the channels CH1 to CHn, via a certain circuit (for example, a receiving circuit). The signal generated based on the pulse signal P_gen received again through the channels CH1 to CHn may be referred to as a pulse signal P_rec. The semiconductor test device 100 may determine whether a signal is modified (e.g., distorted) during a signal transmitting process through the channels CH1 to CHn, based on the pulse signal P_rec received by the receiver 120.

According to some embodiments, a reference level for measuring a width of a signal (e.g., the pulse signal P_gen or the pulse signal P_rec) may be referred to as a first reference level Ref_1, and the semiconductor test device 100 may generate the pulse signal P_gen having a first width w1 at the first reference level Ref_1. The pulse signal P_rec generated based on the pulse signal P_gen by being transmitted or received through the channels CH1 to CHn may be received by the receiver 120. The pulse signal P_rec may have a second width w2 at the first reference level Ref_1 due to an effect, such as damage (e.g., a defect) to the channels CH1 to CHn or the like. For example, the pulse signal P_gen, as a signal having the first width w1, may be determined as normal, but the pulse signal P_rec transmitted or received through the channels CH1 to CHn, as a signal having the second width w2 modified by an effect of the channels CH1 to CHn, may be determined as abnormal. Here, a reference value of a width for determining normality of a signal may be a value between the first width w1 and the second width w2. The first reference level Ref_1 and/or the reference value may be variously realized.

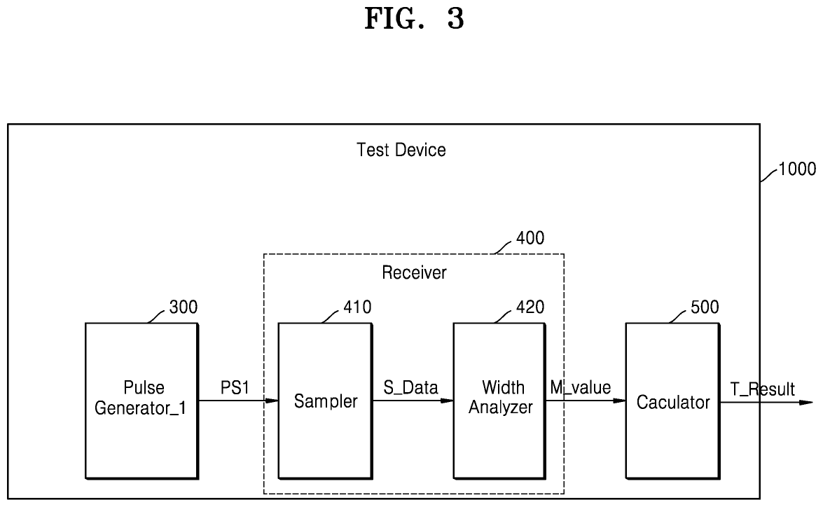

FIG. 3 is a block diagram showing a portion of a semiconductor test device 1000, according to some embodiments.

Referring to FIG. 3, the semiconductor test device 1000 according to some embodiments may include a first pulse signal generator 300, a receiver 400, and a calculator 500. The semiconductor test device 1000 and the receiver 400 may correspond to the semiconductor test device 100 and the receiver 120 of FIG. 1, respectively.

The first pulse signal generator 300 may generate a first pulse signal PS1 that is a test signal, so as to determine whether transmission paths (e.g., channels, such as the channels CH1 to CHn in FIG. 1) of the semiconductor test device 1000 are normal. According to some embodiments, the first pulse signal generator 300 may variously modify the first pulse signal PS1 to adjust (e.g., extend) a test range for the semiconductor test device 1000. For example, the first pulse signal generator 300 may modify a pulse width (e.g., a pulse width at a reference level, such as the first reference level Ref_1 in FIG. 2) and/or a period of the first pulse signal PS1. The first pulse signal generator 300 may transmit the generated first pulse signal PS1 through the transmission paths (e.g., the channels CH1 to CHn in FIG. 1) of the semiconductor test device 1000.

The receiver 400 may receive the first pulse signal PS1 transmitted through the transmission paths of the semiconductor test device 1000. As described above, the receiver 400 may be a configuration generally referring to a configuration for receiving a signal transmitted to the semiconductor test device 1000 (or transmitted or received within the semiconductor test device 1000). For example, the receiver 400 may include a semiconductor chip, such as an FPGA, configured to receive a signal transmitted through the transmission paths. In some embodiment, the receiver 400 may include a sampler 410 and a width analyzer 420. In other words, the sampler 410 and the width analyzer 420 may be realized while being included in the FPGA. In some embodiments, the first pulse signal generator 300 and/or the calculator 500 may be included in the receiver 400. In other words, the receiver 400 may be variously realized as an element configured to receive a signal, without being limited to FIG. 3.

According to some embodiments, the receiver 400 may include the sampler 410. The sampler 410 may receive the first pulse signal PS1 and perform sampling thereon. In detail, the sampler 410 may receive the first pulse signal PS1 that is an analog signal, generate sampling data S_Data by sampling the first pulse signal PS1, based on another pulse signal (e.g., a clock signal or a sampling signal), and output the sampling data S_Data.

Also, according to some embodiments, the receiver 400 may include the width analyzer 420. The width analyzer 420 may measure a width of the first pulse signal PS1 received by the receiver 400, based on the sampling data S_Data generated by the sampler 410. According to some embodiments, the measuring of the width of the first pulse signal PS1 by the width analyzer 420 may be performed by measuring the width of the first pulse signal PS1 at an arbitrary reference level and/or greater, as described with reference to FIG. 2 (e.g., at the first reference level Ref_1 in FIG. 2 and/or greater). The width analyzer 420 may generate a value M_value of the measured width of the first pulse signal PS1 based on the sampling data S_Data.

The calculator 500 may calculate a value of a final width by using the value M_value of the width of the first pulse signal PS1 based on the sampling data S_Data and output a test result T_result including the value of the final width. According to some embodiments, the sampler 410 may perform a sampling operation on the first pulse signal PS1 a plurality of times, and as a result, a plurality of pieces of sampling data S_Data may be generated. The width analyzer 420 may generate the value M_value of the width corresponding to each of the plurality of pieces of sampling data S_Data. The calculator 500 may calculate the value of the final width by using the plurality of values M_value of the widths (e.g., widths of the first pulse signal PS1 based on the plurality of pieces of sampling data S_Data). According to some embodiments, the calculator 500 may calculate an average of the received plurality of values M_value of the widths (e.g., widths of the first pulse signal PS1 based on the plurality of pieces of sampling data S_Data) and determine the average thereof as the value of the final width. Also, according to some embodiments, the calculator 500 may determine abnormality in each of the channels CH1 to CHn as will be described below, by comparing the value of the final width with an initial value of the width of the first pulse signal PS1, and output a result of the determination as the test result T_result. The calculator 500 may be realized in any one of various forms, and according to some embodiments, may be a configuration included in a personal computer (PC) configured to operate the semiconductor test device 1000.

A test device (e.g., the semiconductor test device 1000) according to some embodiments is able to perform sampling of a signal and measuring of a width, based on configurations in the test device, and thus a separate test device may not be required. In other words, because a separate measurer (e.g., an oscilloscope or the like) or an additional configuration may not be required, costs consumed during a test may be greatly reduced.

Also, the test device, according to some embodiments, detects a defect in a transmission path by comparing widths of signals instead of simply identifying whether transmitted or received signals match, and thus, a state of the transmission path may be further precisely measured. Accordingly, a semiconductor yield rate may be increased, and the test device may be efficiently operated.

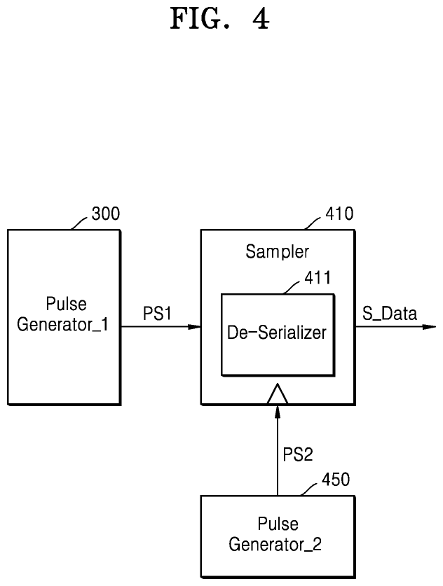

FIG. 4 is a block diagram showing the sampler 410, the first pulse signal generator 300, and a second pulse signal generator 450 of a semiconductor test device, according to some embodiments.

Referring to FIGS. 3 and 4, the sampler 410 may sample the first pulse signal PS1 generated by the first pulse signal generator 300, based on the first pulse signal PS1 and a second pulse signal PS2 generated by the second pulse signal generator 450, and output the sampling data S_Data. As described above, the first pulse signal generator 300 may generate the first pulse signal PS1 and transmit the same to the sampler 410, and the sampler 410 may perform sampling based on the second pulse signal PS2 generated by the second pulse signal generator 450, i.e., a clock signal or a sampling signal. According to some embodiments, the first pulse signal generator 300 may differently vary the first pulse signal PS1 to further adjust (e.g., extend) a test range (or for a further elaborate test). According to some embodiments, the first pulse signal generator 300 may change a period of the first pulse signal PS1 or change a pulse width of the first pulse signal PS1 (e.g., at a reference level, such as the first reference level Ref_1 in FIG. 2). In FIG. 4, the second pulse signal generator 450 may be in the receiver 400. Also, without being limited to FIG. 4, the second pulse signal generator 450 may generate the sampling signal by being located inside the sampler 410 or generate the sampling signal by being located outside the receiver 400.

The sampler 410 may include a de-serializer 411. The de-serializer 411 may perform sampling by receiving and de-serializing a serialized signal, for high-speed communication. Without being limited to FIG. 4, the de-serializer 411 may be located outside the sampler 410 and in this case, the de-serializer 411 may receive a signal, de-serialize the signal, and transmit the same to the sampler 410.

According to some embodiments, the first pulse signal generator 300 and the second pulse signal generator 450 may independently generate a pulse signal. As will be described below, the first pulse signal PS1 generated by the first pulse signal generator 300 and the second pulse signal PS2 generated by the second pulse signal generator 450 may be unsynchronized to each other. In other words, the sampling is performed according to the second pulse signal PS2, irrelevant to the first pulse signal PS1, and thus, a sampling operation for the first pulse signal PS1 by the sampler 410 may start at any one of various arbitrary starting points. Accordingly, when performing sampling on one signal (e.g., the first pulse signal PS1) a plurality of times, the sampler 410 may perform the sampling at various points according to a rising edge or a falling edge of another signal (e.g., the second pulse signal PS2) that is not synchronized. As such, the sampler 410 may convert the first pulse signal PS1 that is an analog signal into the sampling data S_Data that is digital data, through the sampling operation.

In other words, a semiconductor test device according to some embodiments may obtain various pieces of sampling data for one signal by using a sampling signal having various starting points. Accordingly, a width of a pulse of a signal may be further elaborately measured. Also, the semiconductor test device according to some embodiments may further adjust (e.g., extend) a test range while testing a transmission path of a signal by differently varying a pulse signal (i.e., a test signal).

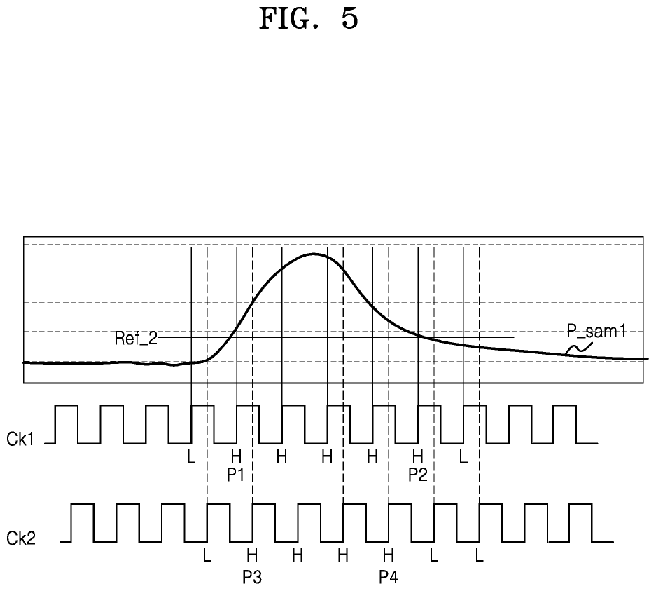

FIG. 5 is a waveform diagram showing a process of sampling a pulse signal P_sam1, according to some embodiments.

Referring to FIGS. 4 and 5, the first pulse signal generator 300 may generate the pulse signal P_sam1 and transmit the same to the sampler 410 through transmission paths (e.g., channels, such as the channels CH1 to CHn in FIG. 1) in a device, and the sampler 410 may receive and sample the pulse signal P_sam1. In detail, the sampler 410 may perform sampling based on another pulse signal (e.g., a clock signal or a sampling signal) of the second pulse signal generator 450.

For example, the sampler 410 may sample the pulse signal P_sam1 at a rising edge of a first clock signal Ck1. A reference level for measuring a width of the pulse signal P_sam1 may be a second reference level Ref_2. In other words, when the pulse signal P_sam1 is sampled at the rising edge of the first clock signal Ck1, the pulse signal P_sam1 may be measured in a case where a level of the pulse signal P_sam1 higher than the second reference level Ref_2 is sampled. As a result, the pulse signal P_sam1 may be measured that a pulse is present between a first point P1 and a second point P2 when sampled according to the first clock signal Ck1, and may be measured that a pulse is present between a third point P3 and a fourth point P4 when sampled according to a second clock signal Ck2.

The second pulse signal generator 450 may independently generate arbitrary sampling signals having various starting points without being synchronized to the first pulse signal generator 300, and thus a pulse signal (e.g., the pulse signal P_sam1) may be sampled at various points. Such sampling may be performed a plurality of times, and thus, a width of the pulse signal (e.g., the pulse signal P_sam1) may be further variously and elaborately measured.

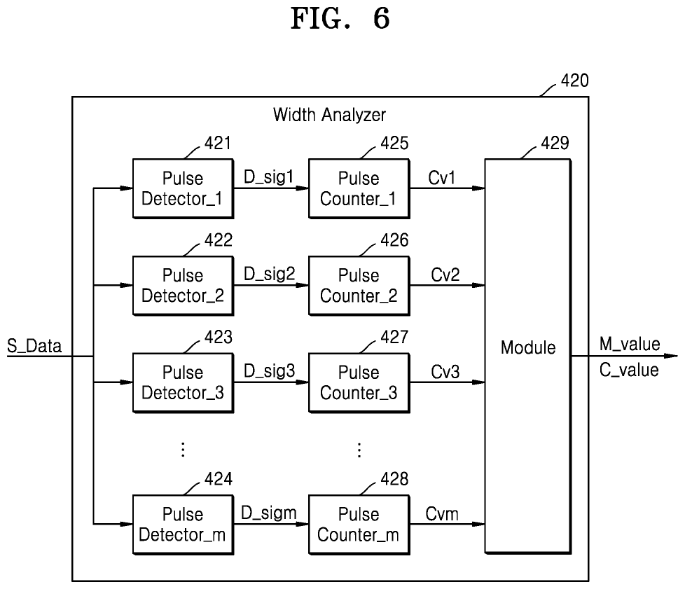

FIG. 6 is a block diagram showing an analyzer configured to measure a width of a pulse signal, according to some embodiments.

Referring to FIG. 6, the width analyzer 420 may measure a width of a pulse signal by receiving the sampling data S_Data and output measurement values (e.g., the value M_value in FIG. 3). The width analyzer 420 may include a first pulse detector 421 to an mth pulse detector 424, a first pulse counter 425 to an mth pulse counter 428, and a module 429.

The first pulse detector 421 may generate a first detection signal D_sig1 when a width (the width of the pulse signal) corresponding to the first pulse detector 421 is detected from among the sampling data S_Data. In more detail, for example, as described above with reference to FIG. 5, one pulse signal may be sampled according to various sampling signals (e.g., the first clock signal Ck1 and/or the second clock signal Ck2) and a plurality of pieces of sampling data S_Data may be transmitted to the width analyzer 420. Here, the first pulse detector 421 may generate the first detection signal D_sig1 when sampling data having a measurement value of a width (the width of the pulse signal) corresponding to (or specific to) the first pulse detector 421 is detected from among the plurality of pieces of sampling data S_Data. The first pulse counter 425 may count (i.e., increase a count value) in response to the first detection signal D_sig1 and output a count result as a first count value Cv1. Similarly, each of the second pulse detector 422 and the third pulse detector 423 to the mth pulse detector 424 may respectively output a second detection signal D_sig2 and a third detection signal D_sig3 to an mth detection signal D_sigm when pieces of sampling data having measurement values of respective widths are detected, and the second pulse counter 426 and the third pulse counter 427 to the mth pulse counter 428 may increase the count values in response to respective detection signals. The module 429 may receive, from the first to mth pulse counters 425 to 428, respective first to mth count values Cv1 to Cvm. In other words, the module 429 may communicate with a calculator or the like by outputting the value M_value of the width (the width of the pulse signal) based on the respective sampling data S_Data and a count value C_value corresponding to the measurement value.

As a result, a semiconductor test device according to some embodiments may further elaborately measure a width of a pulse signal. In other words, as described above, a plurality of pieces of sampling data may be generated based on various arbitrary sampling signals (i.e., signals having various sampling points), and thus, corresponding measurement values may vary. As such, the semiconductor test device according to some embodiments may count by reflecting all different measurement values, thereby further elaborately measuring the width of the pulse signal.

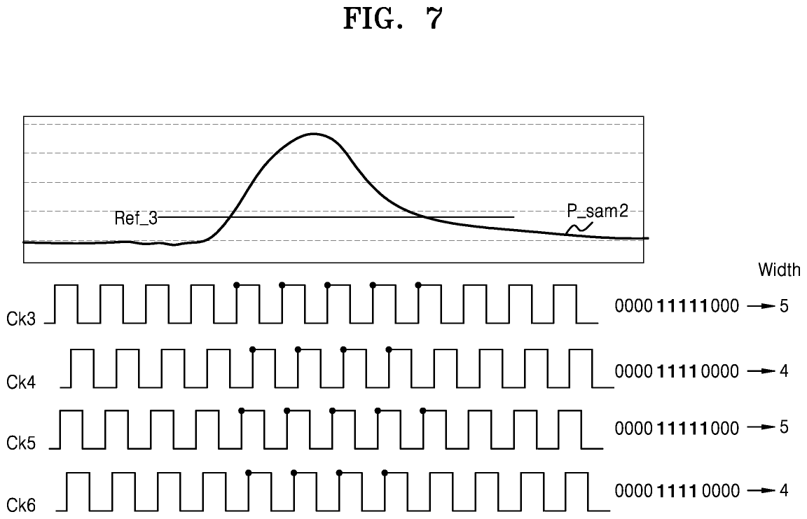

FIG. 7 is a waveform diagram showing a width measuring process according to various types of sampling of a pulse signal P_sam2, according to some embodiments.

Referring to FIGS. 4, 6, and 7, sampling based on various sampling signals (i.e., signals having various sampling points) may be performed, and thus, a width of a pulse signal may be variously measured.

For example, the sampler 410 may sample the pulse signal P_sam2 at a rising edge of a third clock signal Ck3. A reference level for measuring a width of the pulse signal P_sam2 may be a third reference level Ref_3. In other words, when the pulse signal P_sam2 is sampled at the rising edge of the third clock signal Ck3, the pulse signal P_sam2 may be measured in a case where a level of the pulse signalP_sam2 higher than the third reference level Ref_3 is sampled. As a result, the pulse signal P_sam2 may be converted into corresponding digital data (sampling data) as shown in FIG. 7, when sampled according to the third clock signal Ck3. Then, a pulse detector corresponding to a value of a width of the digital data, from among pulse detectors (e.g., the first pulse detector 421 to the mth pulse detector 424 in FIG. 6) of the width analyzer 420, may generate a detection signal (e.g., the first detection signal D_sig1 to the mth detection signal D_sigm) as described above.

The sampler 410 may also sample the pulse signal P_sam2 at a rising edge of a fourth clock signal Ck4, and the pulse signal P_sam2 may be converted into corresponding digital data as shown in FIG. 7, when sampled according to the fourth clock signal Ck4. A pulse detector corresponding to a value of a width of the digital data, from among the pulse detectors (e.g., the first pulse detector 421 to the mth pulse detector 424 in FIG. 6) of the width analyzer 420, may generate a detection signal (e.g., the first detection signal D_sig1 to the mth detection signal D_Sigm in FIG. 6). Here, the value of the width measured based on the third clock signal Ck3 and the value of the width measured based on the fourth clock signal Ck4 may be different from each other, and thus, pulse detectors configured to generate detection signals in response thereto may also be different from each other.

Similarly, sampling may be performed based on a fifth clock signal Ck5 and a sixth clock signal Ck6, and accordingly, values of widths may be differently measured.

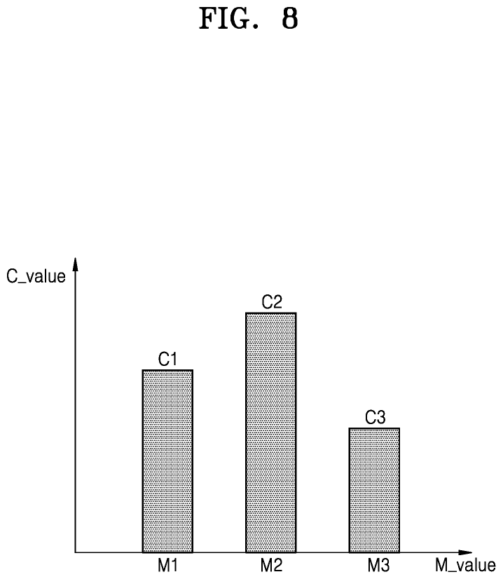

FIG. 8 is a graph for describing a weighted average calculation for a width of a pulse signal, according to some embodiments.

Referring to FIGS. 3, 6, and 8, the calculator 500 may calculate a weighted average by receiving, from the width analyzer 420 (or from the module 429 of the width analyzer 420), the value M_value of the measured width of the pulse signal and the count value C_value.

For example, as described above with reference to FIGS. 6 and 7, values of a width of the pulse signal measured according to various sampling signals may include a first measurement value M1, a second measurement value M2, and a third measurement value M3. In response to each measurement value, a pulse detector (e.g., one of the first pulse detector 421 to the mth pulse detector 424 in FIG. 6) may generate a detection signal (e.g., one of the first detection signal D_sig1 to the mth detection signal D_Sigm in FIG. 6), and in response thereto, a pulse counter (e.g., one of the first pulse counter 425 to the mth pulse counter 428 in FIG. 6) may increase a count value (e.g., one of the first count value Cv1 to the mth count value Cvm in FIG. 6). As a result, sampling data having the first measurement value M1 may have a first count value C1, and count values corresponding to the second measurement value M2 and the third measurement value M3 may respectively have a second count value C2 and a third count value C3. A distribution of such values may be represented by a histogram as shown in FIG. 8.

The calculator 500 may perform calculation of the weighted average, based on the value M_value (e.g., the first to third measurement values M1 to M3) of the measured width of the pulse signal and the corresponding count value C_value (e.g., the first to third count value C1 to C3). For example, a value of the weighted average according to the distribution may be calculated as Equation 1 below.

$$Weighted Average = \frac{M 1 * C 1 + M 2 * C 2 + M 3 * C 3}{C 1 + C 2 + C 3} \qquad [ Equation 1 ]$$

In other words, as described above, a pulse width may be measured based on signals having various sampling points. A semiconductor test device according to some embodiments may count by reflecting all different relevant measurement values and calculate a weighted average based thereon, thereby further elaborately measuring a width of a pulse signal.

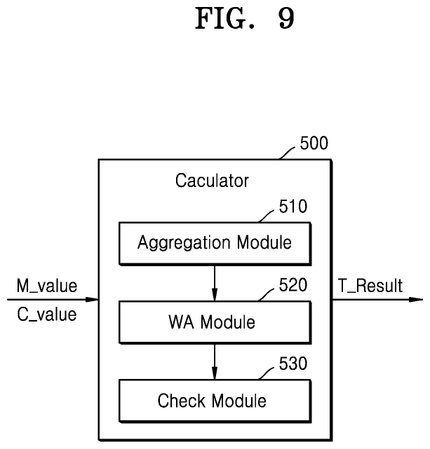

FIG. 9 is a block diagram showing the calculator 500 of a semiconductor test device, according to some embodiments.

Referring to FIG. 9, the calculator 500 may include an aggregation module 510, a weighted average (WA) module 520, and a check module 530. As described above, the calculator 500 may be a configuration configured to perform calculation based on measured values (e.g., the value M_value) and determine abnormality, and may be embodied in various forms. For example, the calculator 500 may include a processor or may be included in a PC configured to operate a semiconductor test device (e.g., the semiconductor test device 1000 in FIG. 3).

The aggregation module 510 may receive the value M_value of the measured width of the pulse signal and the count value C_value and aggregate values respectively corresponding to signal transmission paths (e.g., channels, such as the channels CH1 to CHn in FIG. 1). For example, because effects of the channels on signal transmission may be different from each other, the values may also be different from each other. The aggregation module 510 may transmit the aggregated values to the WA module 520.

The WA module 520 may calculate a weighted average as described above with reference to FIG. 8, for each of the signal transmission paths, based on the received values. The WA module 520 may transmit, to the check module 530, a calculation value (i.e., a value of a width of a pulse signal transmitted or received through the transmission path).

The check module 530 may determine abnormality of each of the transmission paths, based on a received weighted average value. According to some embodiments, the check module 530 may compare the weighted average value of the width of the pulse signal with an initial value. A case in which a difference between the weighted average value and the initial value is greater than an arbitrary reference value may denote that a signal has been modified due to an effect of a corresponding transmission path. Accordingly, the check module 530 may determine that the corresponding transmission path is abnormal and display an abnormal path. Also, according to some embodiments, the check module 530 may compare the weighted average value of the width of the pulse signal for each transmission path with the initial value, thereby indicating normality (or healthiness) of each transmission path, i.e., how much a transmitted signal is affected by the transmission path. For example, the normality may be low when the difference between the weighted average value and the initial value is high. The check module 530 may output above-described diagnosis results, and at least one of the diagnosis results may be included in the test result T_result described above with reference to FIG. 3.

In other words, a semiconductor test device according to some embodiments may further elaborately measure a width of a pulse signal through calculation of a weighted average, precisely diagnose abnormality of each of signal transmission paths, based on a measurement value, and display normality. Accordingly, even a minor defect of a transmission path may be detected and detection itself may be further quickly performed. In addition, it may be quickly specified and determined which transmission path reduces a yield rate and which transmission path needs to be compensated for.

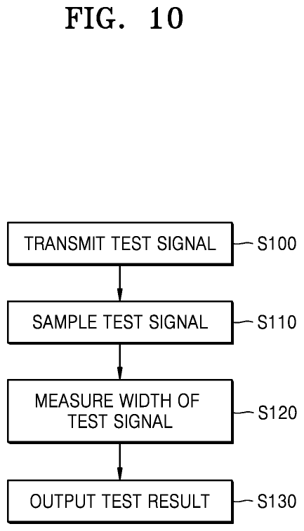

FIG. 10 is a flowchart of a method of testing the semiconductor test device 1000, according to some embodiments.

Referring to FIGS. 3 and 10, the method according to some embodiments may include diagnosing each of transmission paths by generating a test signal and transmitting or receiving the same through the transmission paths.

First, the first pulse signal generator 300 of the semiconductor test device 1000 may generate the first pulse signal PS1 as a test signal and transmit the same to the sampler 410 through transmission paths (operation S100). The sampler 410 may perform sampling by receiving the test signal (operation S110). According to some embodiments, as described above with reference to FIG. 4, the sampling may be performed based on a signal (e.g., the clock signal or the sampling signal) generated independently from the test signal. In other words, a sampling operation on the test signal may start at various arbitrary starting points, as sampling is performed on arbitrary signals that are not synchronized with the test signal. Then, the width analyzer 420 may measure a width of the transmitted or received test signal, based on a sampling result (operation S120). As described above with reference to FIG. 2, the width of the test signal may be measured by measuring a signal having an arbitrary reference level or greater. The calculator 500 may output a value of the measured width as a test result (operation S130). Also, according to some embodiments, the calculator 500 may output, as the test result, a diagnosis result of each transmission path, based on the value of the measured width. As will be described below, the test result may include at least one of normality of each transmission path, damage to each transmission path, and necessity to compensate for each transmission path.

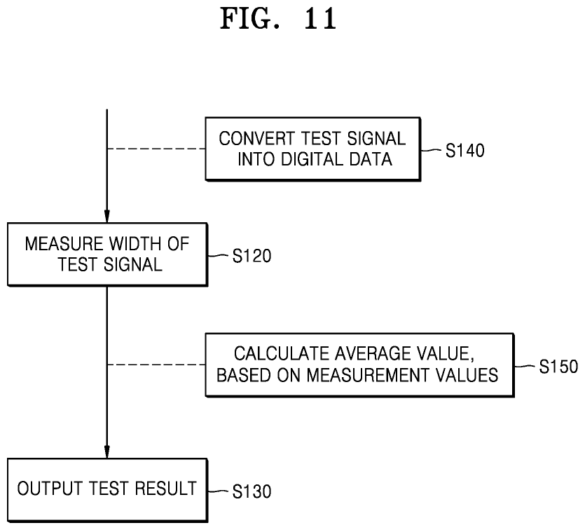

FIG. 11 is a flowchart of a width measuring method and/or an average value calculating method for a test signal, according to some embodiments.

Referring to FIGS. 10 and 11, a method of testing a semiconductor test device, according to some embodiments, may include converting a test signal into digital data according to sampling, and measuring a width of the test signal by performing the sampling a plurality of times.

According to some embodiments, as described above, the test signal may be sampled at various arbitrary points, and the test signal that is an analog signal may be converted into digital data as shown in FIG. 7, through a sampling operation described above (operation S140).

According to some embodiments, when the sampling is performed on one test signal a plurality of times (in particular, performed according to arbitrary sampling signals), a measurement value of the width analyzer 420 may be different according to the sampling signals. The calculator 500 may receive such different measurement values and calculate an average value (operation S150). The calculator 500 may determine the average value as a final width of the test signal and output the same as a test result.

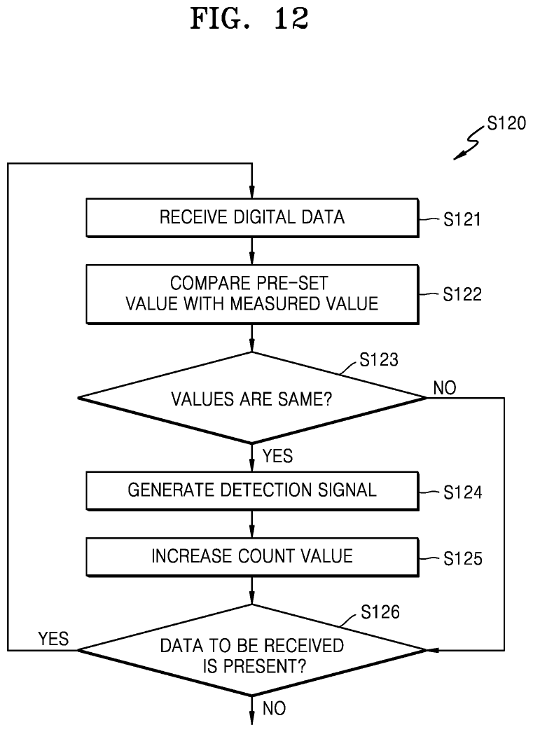

FIG. 12 is a flowchart of a process for measuring a width of a test signal, according to some embodiments.

Referring to FIGS. 6 and 12, a method of testing a semiconductor test device, according to some embodiments, may further elaborately measure a width of a test signal, based on sampling data described above, i.e., digital data.

First, the width analyzer 420 may receive sampled digital data (operation S121). The first pulse detector 421 may compare a value of a width based on the received digital data with a value corresponding to (or pre-set to) the first pulse detector 421 (operation S122). In detail, it may be determined whether the value of the measured width and the corresponding value are the same (operation S123), and when the values are the same, the first pulse detector 421 may generate a detection signal because the value of the corresponding width has been detected (operation S124). The generated detection signal may be transmitted to the first pulse counter 425, and the first pulse counter 425 may increase a count value by receiving the detection signal (operation S125). Then, a measuring operation may be repeated by identifying whether there is digital data to be detected (or received) (operation S126). On the other hand, when the value of the measured width and the corresponding value do not match each other, a pulse detector does not operate, and thus, a counting operation is also not performed. Accordingly, the measurement operation may be repeated by identifying whether there is digital data to be detected, without detection signal generation and counting operation (operation S126).

In other words, the method according to some embodiments may further elaborately measure a width of a test signal. The method according to some embodiments may further elaborately measure the width of the test signal by counting by reflecting all different measurement values of a plurality of pieces of digital data generated based on signals having various sampling points.

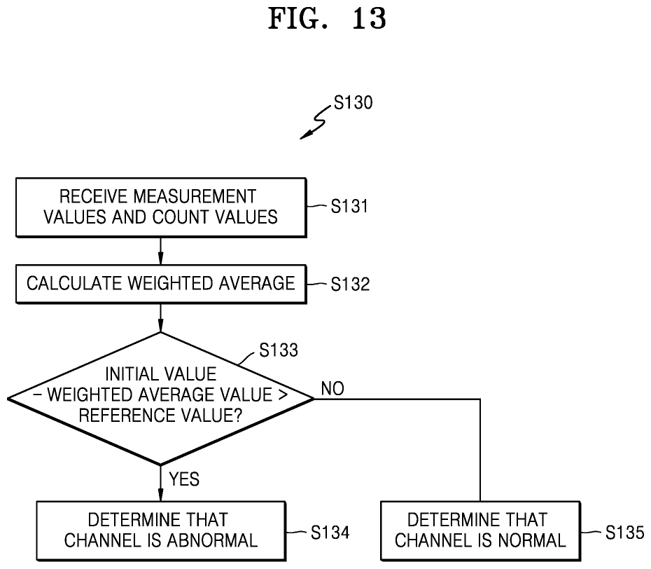

FIG. 13 is a flowchart of a weighted average calculating process for a width of a test signal, according to some embodiments.

Referring to FIGS. 9 and 13, a method of testing a semiconductor test device, according to some embodiments, may include calculating a weighted average value by using measurement values and determining abnormality of a transmission path, based thereon.

First, the calculator 500 may receive values M_value of a measured width of a test signal and count values C_value (operation S131). The calculator 500 may calculate a weighted average value of a width of the test signal as described above with reference to FIG. 8, based on the received values (operation S132). Then, the calculator 500 may determine whether a difference between the value of the width of the test signal and the weighted average value is greater than a reference value (operation S133). When the difference is greater than the reference value, a signal may have been modified by an effect of a corresponding transmission path (e.g., a channel of the channels CH1 to CHn), and thus, the corresponding transmission path may be determined to be abnormal (operation S134). On the other hand, when the difference is less than the reference value, the corresponding transmission path may be determined to be normal (operation S135). Also, according to some embodiments, the calculator 500 may indicate how much normality (or healthiness) of each transmission path, i.e., a transmitted test signal, is affected by the transmission path.

In other words, the method according to an embodiment may further elaborately measure a width of a test signal through calculation of a weighted average, precisely diagnose abnormality and minor defect of each of signal transmission paths, based on a measurement value, and display normality.

While the inventive concept of the present disclosure has been particularly shown and described with reference to embodiments thereof, it will be understood that various changes in form and details may be made therein without departing from the spirit and scope of the following claims.

What is claimed is:

1. A test device for testing a semiconductor, the test device comprising:
a pulse signal generator that is configured to generate a first pulse signal and transmit the first pulse signal through channels;
a sampler that is configured to receive the first pulse signal through the channels and conduct a sampling process on the first pulse signal, based on a second pulse signal;
a width analyzer that is configured to measure a first width of the first pulse signal and generate a first measurement value, based on a result of the sampling process; and
a calculator that is configured to output a test result corresponding to each of the channels of the test device, based on the first measurement value.

2. The test device of claim 1, wherein the test device is configured to generate the first pulse signal and the second pulse signal independently.

3. The test device of claim 1, wherein the width analyzer is further configured to measure a plurality of widths of the first pulse signal and generate a plurality of measurement values, based on the result of the sampling process, and
wherein the calculator is further configured to calculate an average value of the plurality of widths of the first pulse signal, based on the plurality of measurement values, and output the average value as the test result.

4. The test device of claim 1, wherein the sampler comprises a de-serializer that is configured to de-serialize the first pulse signal.

5. The test device of claim 1, wherein the sampler is further configured to convert the first pulse signal into digital data based on the sampling process.

6. The test device of claim 5, wherein the width analyzer is further configured to measure a plurality of widths of the first pulse signal and generate a plurality of measurement values, based on the result of the sampling process, and
wherein the width analyzer comprises a detector that is configured to generate a detection signal when a corresponding measurement value to the detector among the plurality of measurement values is detected, based on the digital data.

7. The test device of claim 6, wherein the width analyzer further comprises a counter corresponding to the detector, and
the counter is configured to count in response to the detection signal and generate a counting value.

8. The test device of claim 7, wherein the calculator is further configured to calculate a weighted average value of the plurality of widths of the first pulse signal, based on the counting value and the plurality of measurement values.

9. The test device of claim 8, wherein the calculator is further configured to output the test result by comparing an initial width value of the first pulse signal with the weighted average value.

10. The test device of claim 1, wherein the pulse signal generator is further configured to vary at least one of a width of the first pulse signal and a period of the first pulse signal.

11. The test device of claim 1, wherein the test device further comprises a field programmable gate array (FPGA) that is configured to receive a signal, and wherein at least one of the sampler and the width analyzer is included in the FPGA.

12. The test device of claim 1, wherein the test device further comprises a printed circuit board (PCB), a cable, and a connector, and
wherein each of the channels is included in at least one of the PCB, the cable, and the connector.

13. A test device for testing a semiconductor, the test device comprising:
a pulse signal generator that is configured to generate a test signal;
a plurality of channels that is configured to transmit the test signal;
a sampler that is configured to receive the test signal through at least one channel of the plurality of channels and conduct a sampling process on the test signal based on a pulse signal;
a width analyzer that is configured to generate a first measurement value by measuring a first width of the test signal based on a result of the sampling process; and
a calculator that is configured to output a test result corresponding to each of the at least one channel of the test device, based on the first measurement value.

14. The test device of claim 13, wherein the test device is configured to generate the test signal and the pulse signal independently.

15. The test device of claim 13, wherein the width analyzer is further configured to measure a plurality of widths of the test signal and generate a plurality of measurement values, based on the result of the sampling process, and
wherein the calculator is further configured to calculate an average value of the plurality of widths of the test signal, based on the plurality of measurement values, and output the average value as the test result.

16. The test device of claim 13, wherein the sampler is further configured to convert the test signal into digital data based on the sampling process.

17. The test device of claim 16, wherein the width analyzer is further configured to measure a plurality of widths of the test signal and generate a plurality of measurement values, based on the result of the sampling process, and
wherein the width analyzer comprises a detector that is configured to generate a detection signal when a corresponding measurement value to the detector among the plurality of measurement values is detected, based on the digital data.

18. The test device of claim 17, wherein the width analyzer further comprises a counter corresponding to the detector, and
the counter is configured to count in response to the detection signal and generate a counting value.

19. The test device of claim 18, wherein the calculator is further configured to calculate a weighted average value of the plurality of widths of the test signal, based on the counting value and the plurality of measurement values, and
output the test result by comparing an initial width value of the test signal with the weighted average value.

20. A test device that is configured to test a semiconductor device,
wherein the test device is further configured to:
generate a test signal and transmit the test signal through channels;
convert the test signal into digital data by sampling the test signal;
measure values of widths of the test signal, based on the digital data;
generate a detection signal by detecting a corresponding value of a width of the test signal among the values of the widths of the test signal;
count in response to the detection signal to generate a counting result; and
calculate a weighted average value of the values of the widths of the test signal, based on the counting result and the values of the widths of the test signal.
